(19) United States
(12) Patent Application Publication
(10) Pub. No.: US 2015/0263176 A1
(43) Pub. Date: Sep. 17, 2015

(54) THIN FILM TRANSISTOR AND MANUFACTURING METHOD FOR THE SAME

(71) Applicant: National Taiwan Normal University, Taipei (TW)

(72) Inventor: Chun-Hu CHENG, Taipei (TW)

(73) Assignee: National Taiwan Normal University

(21) Appl. No.: 14/657,275

(22) Filed: Mar. 13, 2015

(30) Foreign Application Priority Data
Mar. 13, 2014 (TW) 103108871

(51) Int. Cl. H01L 29/786; H01L 29/10; H01L 29/66

(52) U.S. Cl. CPC H01L 29/7869; H01L 29/66969; H01L 29/1054

(57) ABSTRACT

A thin film transistor and a manufacturing method for the same are provided. The thin film transistor comprises a substrate, a double channel semiconductor layer, a semiconductor passivation layer, a gate, a gate dielectric layer, a source and a drain. The double channel semiconductor layer comprises a first semiconductor layer and a second semiconductor layer. The first semiconductor layer is made of a metallic oxide semiconductor material and formed above the substrate. The second semiconductor layer is made of the metallic oxide semiconductor material doped by an oxygen gettering metal and formed on the first semiconductor layer. The semiconductor passivation layer is formed on the second semiconductor layer. The gate is formed above the substrate. The gate dielectric layer is formed between the gate and the double channel semiconductor layer. The source and drain are close to the double channel semiconductor layer, formed above the substrate and electrically connected to the double channel semiconductor layer.

### FIELD OF THE INVENTION

The present invention relates to a thin film transistor and a manufacturing method for the same, and particularly to a thin film transistor using a metallic oxide semiconductor and a manufacturing method for the same.

### BACKGROUND OF THE INVENTION

FIG. 1 is a schematic structural diagram of a conventional bottom-gate thin film transistor (TFT), whose specific structure is as follows: an insulation layer 12 is formed on a substrate 11, then a metal gate 13, a gate dielectric layer 14, a channel layer (active layer) 15, a source 16 and a drain 17 are sequentially formed on the insulation layer 12, and a passivation layer 18 is formed on the source 16 and the drain 17. In the structure of the conventional TFT 1, the channel layer 15 is used as a region where a carrier moves from the source 16 to the drain 17, and the characteristics of the TFT 1 mainly depend on the channel layer 15. For example, the component performance of the TFT 1 depends on the material, element ratios, concentration of oxygen vacancies, carrier concentration and other factors of the channel layer 15.

In the prior art, amorphous Si and poly Si are mostly used as the channel layer 15 of the TFT, which is widely used in liquid crystal displays (LCDs), to serve as switches for pixels and voltage sources for liquid crystal. However, the field effect mobility (μ_{FE}) of carriers of the amorphous Si TFT is about 1 cm²/Vs, which limits development for high resolution displays. The poly Si TFT has a complex process, a high thermal budget and low uniformity, and cannot meet the demands of the future display development trend for flexible and transparent displays under focus. As the oxide semiconductor TFT has higher carrier mobility (about 10 cm²/Vs) in comparison to the amorphous Si TFT, and has a lower-temperature process and more uniform characteristics as compared with the poly Si TFT, the oxide semiconductor TFT quickly attracts attention from the industries.

Recently, the material of the channel layer 15 adopts ZnO, InGaZnO (IGZO) and other oxide semiconductors to replace the amorphous Si or poly Si used by the original channel layer 15. This is because, compared with Si-based materials, the oxide semiconductors have the characteristics of being transparent to visible light, and transistors with high carrier mobility (about 10 cm²/Vs) and high uniformity can be made under low-temperature processes (<300° C.). The low-temperature processes may be used in plastic substrates, and facilitate development of transparent and flexible displays. However, compared with the carrier mobility (tens to hundreds) of the poly Si TFT, the carrier mobility of the oxide semiconductor TFT still has room for improvement. FIG. 6 is a characteristic diagram of a drain current-gate voltage (I_{D}-V_{G}) of the conventional TFT 1. The channel layer 15 of the conventional TFT 1 uses IGZO, while the gate dielectric layer 14 uses HfO₂/TiO₂, and the field effect mobility (μ_{FE}) thereof is merely 3 cm²/Vs.

To further enhance resolution and response speed of applications such as active-matrix organic light-emitted diode (AMOLED) displays or operational speed of applications such as memory and other computing chips, improving the carrier mobility is a must.

### SUMMARY OF THE INVENTION

An objective of the present invention is to provide a high-performance TFT and a manufacturing method for forming the TFT. The TFT can improve component characteristics of a conventional TFT and provide high field effect mobility (μ_{FE}), low subthreshold swing (S.S.) and a low off current, so as to facilitate the development of new-generation, low-power, high-performance TFT components.

A TFT according to one embodiment includes a substrate, a double channel semiconductor layer, a semiconductor passivation layer, a gate, a gate dielectric layer, a source and a drain. The double channel semiconductor layer includes a first semiconductor layer and a second semiconductor layer. The first semiconductor layer is made of a metallic oxide semiconductor material and formed above the substrate. The second semiconductor layer is made of the metallic oxide semiconductor material doped by an oxygen gettering metal and formed on the first semiconductor layer. The semiconductor passivation layer is formed on the second semiconductor layer. The semiconductor passivation layer protects the double channel semiconductor layer and is semiconducting. The gate is formed above the substrate. The gate dielectric layer is formed between the gate and the double channel semiconductor layer. The source is close to the double channel semiconductor layer, formed above the substrate and electrically connected to the double channel semiconductor layer. The drain is spaced apart from the source, close to the double channel semiconductor layer, formed above the substrate, and electrically connected to the double channel semiconductor layer.

A manufacturing method for forming a TFT according to one embodiment includes (a) providing a substrate; (b) forming a double channel semiconductor layer, the double channel semiconductor layer including: a first semiconductor layer made of a metallic oxide semiconductor material and formed above the substrate, and a second semiconductor layer made of the metallic oxide semiconductor material doped by an oxygen gettering metal and formed on the first semiconductor layer; (c) forming a semiconductor passivation layer on the second semiconductor layer, wherein the semiconductor passivation layer protects the double channel semiconductor layer and is semiconducting; (d) forming a gate above the substrate; (e) forming a gate dielectric layer between the gate and the double channel semiconductor layer; (f) forming a source close to the double channel semiconductor layer, formed above the substrate and electrically connected to the double channel semiconductor layer; and (g) forming a drain spaced apart from the source, close to the double channel semiconductor layer, above the substrate and electrically connected to the double channel semiconductor layer.

### BRIEF DESCRIPTION OF THE DRAWING

FIG. 1 is a schematic structural view of a conventional TFT;

FIG. 2 is a schematic structural view of a first embodiment of a TFT;

FIG. 3A to FIG. 3G are schematic views of manufacturing processes of the first embodiment of the TFT;

FIG. 4 is a schematic structural view of a second embodiment of the TFT;

FIG. 5A to FIG. 5G are schematic views of manufacturing processes of the second embodiment of the TFT;

FIG. 6 is a characteristic diagram of a drain current-gate voltage (I_{D}-V_{G}) of the conventional TFT;

FIG. 7 is a characteristic diagram of a drain current-gate voltage (I_{D}-V_{G}) of the TFT according to the present embodiment; and

FIG. 8 is a component characteristics comparison diagram of carrier mobility (μ_{FE}) and subthreshold swing (S.S.) of the second semiconductor layer with different thicknesses.

### DETAILED DESCRIPTION OF THE INVENTION

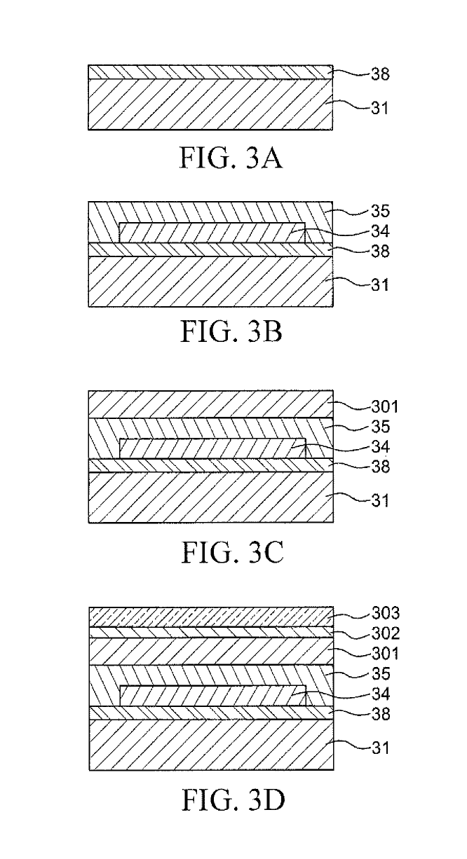

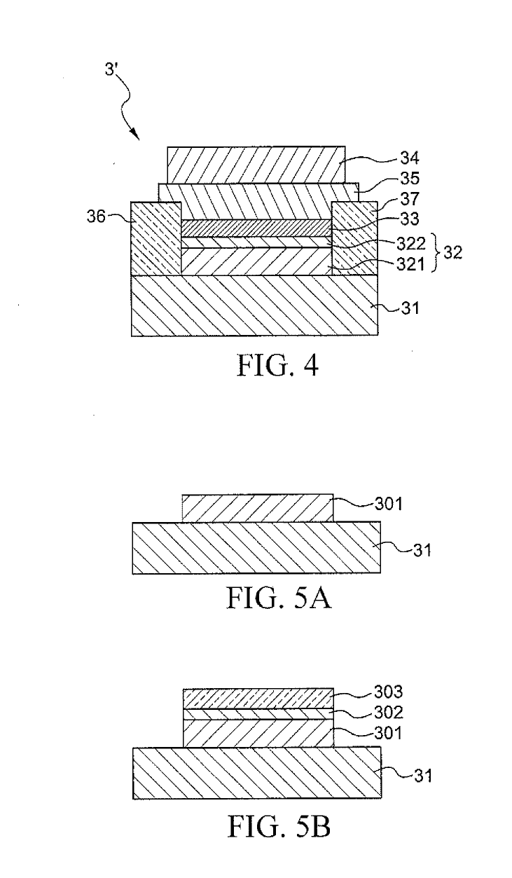

Referring to FIG. 2 or FIG. 4, the basic structure of the TFT 3, 3′ according to the present embodiment includes: a substrate 31, a double channel semiconductor layer 32, a semiconductor passivation layer 33, a gate 34, a gate dielectric layer 35, a source 36 and a drain 37. The double channel semiconductor layer 32 includes a first semiconductor layer 321 and a second semiconductor layer 322. The first semiconductor layer 321 is made of a metallic oxide semiconductor material. The second semiconductor layer 322 is made of the same metallic oxide semiconductor material doped by an oxygen gettering metal and formed on the first semiconductor layer 321. The semiconductor passivation layer 33 is formed on the second semiconductor layer 322. The semiconductor passivation layer 33 protects the double channel semiconductor layer 32 and is semiconducting. The gate dielectric layer 35 is formed between the gate 34 and the double channel semiconductor layer 32. The source 36 is formed close to the double channel semiconductor layer 32 and electrically connected to the double channel semiconductor layer 32. The drain 37 is spaced apart from the source 36, close to the double channel semiconductor layer 32 and electrically connected to the double channel semiconductor layer 32. The first semiconductor layer 321, the second semiconductor layer 322, the gate 34, the source 36 and the drain 37 are not all directly close to the substrate 31 in the following embodiments but are all located above the substrate 31.

Referring to FIG. 2, a first embodiment is a bottom-gate TFT 3. In the TFT 3 according to the first embodiment, the gate 34 is formed on the substrate 31, the gate dielectric layer 35 is formed on the gate 34, the first semiconductor layer 321 is formed on the gate dielectric layer 35, and the source 36 and the drain 37 are formed on the semiconductor passivation layer 33. If the substrate 31 is not an insulating substrate, the TFT 3 further includes an insulation layer 38, and the insulation layer 38 is formed between the substrate 31 and the gate 34 to serve as an insulation layer between the gate 34 and the substrate 31. If the substrate 31 per se has an effect of being insulated from the gate 34, it is also feasible that the insulation layer 38 is not formed.

Referring to FIG. 4, a second embodiment is a top-gate TFT 3′. In the TFT 3′ according to the second embodiment, the first semiconductor layer 321 is formed on the substrate 31; the source 36 and the drain 37 are formed on the substrate 31 and laterally contact the first semiconductor layer 321, the second semiconductor layer 322 and the semiconductor passivation layer 33; the gate dielectric layer 35 is formed on the semiconductor passivation layer 33, the source 36 and the drain 37; and the gate 34 is formed on the gate dielectric layer 35.

The substrate 31 may be a semiconductor substrate, for example, a silicon substrate, may also be an insulating substrate, for example, a plastic substrate or a glass substrate, or may be a metal substrate.

In the double channel semiconductor layer 32, the metallic oxide semiconductor material used for forming the first semiconductor layer 321 and the second semiconductor layer 322 may be IGZO, IGO, IZO, GZO, ZnO or other similar materials. Preferably, the metallic oxide semiconductor material is IGZO.

The second semiconductor layer 322 of the present embodiments is made of the metallic oxide semiconductor material doped by an oxygen gettering metal, and the second semiconductor layer 322 has efficacy of enhancing the carrier mobility in the TFT 3, 3′. The oxygen gettering metal doped in the second semiconductor layer 322 may be W, Sb, Ti, Sn, Al, Hf, Ga, La, Y, Sc or other similar materials. Preferably, the oxygen gettering metal is Ti. A thickness of the second semiconductor layer 322 is 1-100 nm. Preferably, the thickness of the second semiconductor layer 322 is 1-20 nm.

The semiconductor passivation layer 33, which is formed on the second semiconductor layer 322, has an effect of blocking moisture and oxygen in the atmosphere and avoiding that the channel layer becomes damp, and is semiconducting. The semiconductor passivation layer 33 may be made of TiO₂, PbZrTiO₃, BaTiO, SrTiO, ZnO, SnO₂, NiO, Ga₂O₃, Nb₂O₅, CeO₂, Cr₂O₃, Mn₂O₃, WO₃, CoO, Co₃O₄, Fe₂O₃, In₂O₃, ITO, AZO (AlZnO) or other similar materials. A thickness of the semiconductor passivation layer 33 is 1-100 nm. Preferably, the thickness of the semiconductor passivation layer 33 is 1-20 nm.

Taking the bottom-gate TFT 3 according to the first embodiment of the present embodiment shown in FIG. 2 as an example, the semiconductor passivation layer 33 is placed on the double channel semiconductor layer 32 and under the source 36 and the drain 37. The semiconductor passivation layer 33 of the present embodiments is different from a conventional passivation layer 18, which is described as follows:

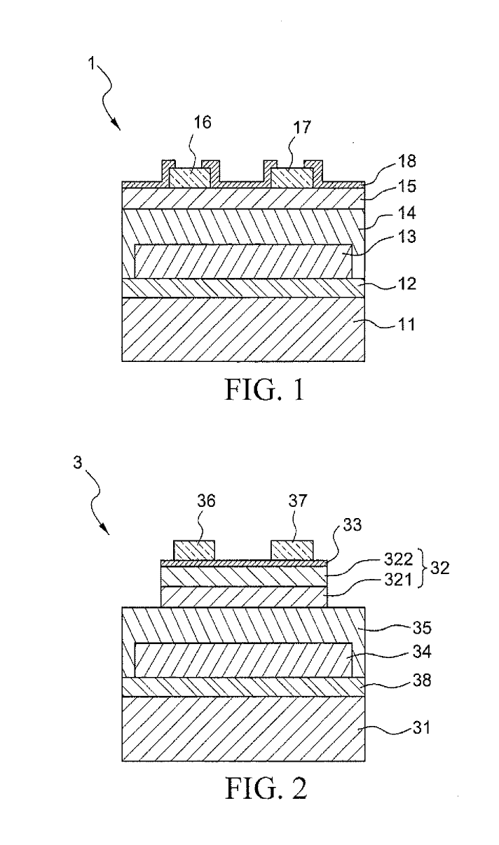

(1) As shown in FIG. 1, the conventional passivation layer 18 is placed on the source 16 and the drain 17, and therefore the source 16 and the drain 17 directly contact the channel layer 15. The semiconductor passivation layer 33 of the present embodiment is disposed between the source 36 as well as the drain 37 and the double channel semiconductor layer 32, so the source 36 and the drain 37 are not in direct contact with the double channel semiconductor layer 32.

(2) An insulator is selected as the material of the conventional passivation layer 18, for example, SiO₂, SiNₓ and other materials to avoid a short circuit between the source 16 and the drain 17. An oxide, which is semiconducting, is selected for the semiconductor passivation layer 33 of the present embodiments, so, when a voltage is applied to the gate 34, the semiconductor passivation layer 33 and the double channel semiconductor layer 32 may be in an on state, a carrier may flow to the semiconductor passivation layer 33 via the source 36, then is transferred to the double channel semiconductor layer 32 from the semiconductor passivation layer 33, and finally flows out to the drain 37 via the semiconductor passivation layer 33.

The gate 34 is formed above the substrate 31. If the insulation layer 38 is present, the insulation layer 38 is located between the gate 34 and the substrate 31. The gate 34 may be made of TaN, Al, titanium silver alloy (Ti/Ag), ITO, Mo or other similar materials. The gate dielectric layer 35 is formed between the gate 34 and the double channel semiconductor layer 32. The gate dielectric layer 35 may be made of SiO₂, SiNₓ, HfO₂, Y₂O₃, TiO₂, GeO₂, Al₂O₃ or other similar materials.

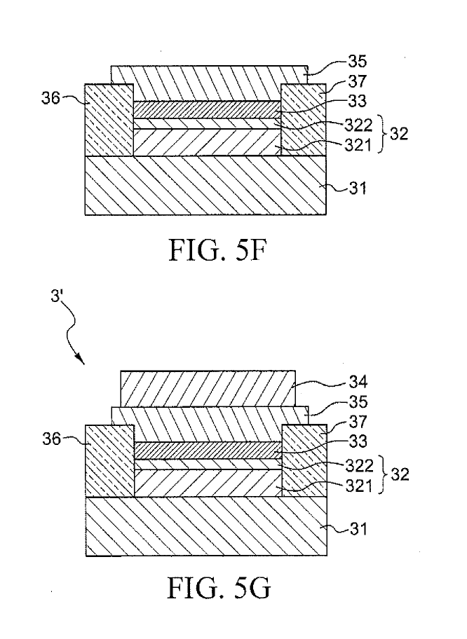

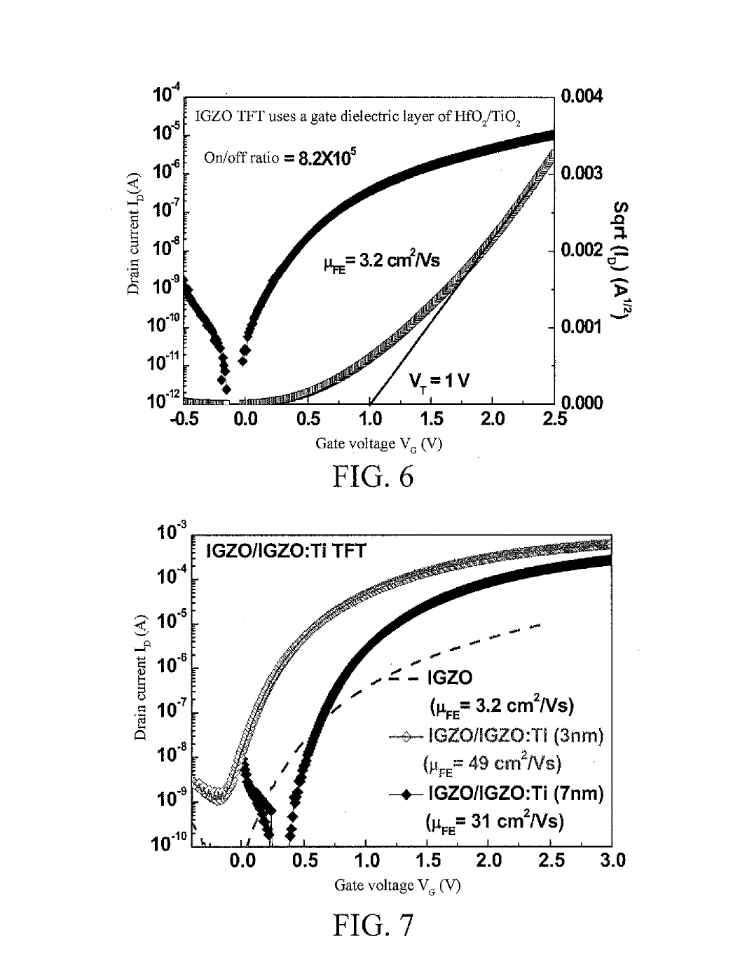

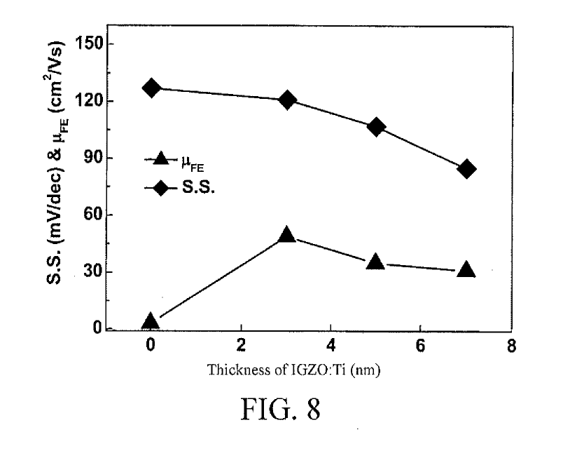

FIG. 6 is a characteristic diagram of a drain current-gate voltage (I_{D}-V_{G}) of the conventional TFT 1. The field effect mobility (μ_{FE}) is merely 3.2 cm²/Vs. FIG. 7 is a characteristic diagram of a drain current-gate voltage (I_{D}-V_{G}) of the TFT 3, 3′ according to the present embodiments. The second semiconductor layer 322 of the TFT 3, 3′ of the present embodiments is made of the metallic oxide semiconductor material doped by an oxygen gettering metal. FIG. 8 is a component characteristics comparison diagram of carrier mobility (that is, field effect mobility μ_{FE}) and subthreshold swing (S.S.) of the second semiconductor layer 322 doped by an oxygen gettering metal with different thicknesses. The second semiconductor layer 322 doped by an oxygen gettering metal herein uses Ti doped IGZO, labeled as IGZO:Ti. The thickness 0 nm indicates the absence of the second semiconductor layer 322 doped by the oxygen gettering metal.

Referring to FIG. 7 and FIG. 8, when the thickness of the second semiconductor layer 322 doped by the oxygen gettering metal is 7 nm, the carrier mobility can be enhanced to about 30 cm²/Vs from about 3 cm²/Vs of the conventional TFT 1 made of the metallic oxide semiconductor material not doped by an oxygen gettering metal. The subthreshold swing (S.S.) of the component is significantly reduced to about 85 mV/dec from 121 mV/dec of the conventional TFT 1. These improvements to the component characteristics of the TFT help to enhance resolution of display products or operational speeds of computing components. When the thickness of the second semiconductor layer 322 doped by the oxygen gettering metal is 3 nm, the carrier mobility can be further enhanced to about 50 cm²/Vs. The result indicates that the TFT 3, 3′ of the present embodiments may have efficacy of enhancing the carrier mobility.

FIG. 2 illustrates the first embodiment, which is a “bottom-gate TFT 3”. A manufacturing method for the TFT 3 according to the first embodiment includes the following steps: (a) providing a substrate 31; (b) forming a gate 34 on the substrate 31; (c) forming a gate dielectric layer 35 on the gate 34; (d) forming a double channel semiconductor layer 32 on the gate dielectric layer 35, the double channel semiconductor layer 32 including: a first semiconductor layer 321 made of a metallic oxide semiconductor material; and a second semiconductor layer 322 made of the metallic oxide semiconductor material doped by an oxygen gettering metal and formed on the first semiconductor layer 321; (e) forming a semiconductor passivation layer 33 on the second semiconductor layer 322, wherein the semiconductor passivation layer 33 protects the double channel semiconductor layer 32 and is semiconducting; (f) forming a source 36 on the semiconductor passivation layer 33, which is close to the double channel semiconductor layer 32 and electrically connected to the double channel semiconductor layer 32; and (g) forming a drain 37 on the semiconductor passivation layer 33, which is spaced apart from the source 36, close to the double channel semiconductor layer 32 and electrically connected to the double channel semiconductor layer 32. If the substrate 31 is not an insulating substrate, the manufacturing method for forming the TFT 3 further includes, between steps (a) and (b), a step (h) of forming an insulation layer 38 on the substrate 31 to make the insulation layer between the substrate 31 and the gate 34. If the substrate 31 per se has an effect of being insulated from the gate 34, it is also feasible that the insulation layer 38 is not formed.

FIG. 4 illustrates the second embodiment, which is a top-gate TFT 3′. A manufacturing method for forming the TFT 3′ according to the second embodiment further includes the following steps: (a) providing a substrate 31; (b) forming a double channel semiconductor layer 32 on the substrate 31, the double channel semiconductor layer 32 including: a first semiconductor layer 321 made of a metallic oxide semiconductor material; and a second semiconductor layer 322 made of the metallic oxide semiconductor material doped by an oxygen gettering metal and formed on the first semiconductor layer 321; (c) forming a semiconductor passivation layer 33 on the second semiconductor layer 322, wherein the semiconductor passivation layer 33 protects the double channel semiconductor layer 32 and is semiconducting; (d) forming a source 36 close to the double channel semiconductor layer 32 and electrically connected to the double channel semiconductor layer 32; (e) forming a drain 37 spaced apart from the source 36, close to the double channel semiconductor layer 32 and electrically connected to the double channel semiconductor layer 32; (f) forming a gate dielectric layer 35 on the semiconductor passivation layer 33; and (g) forming a gate 34 on the gate dielectric layer 35. In step (d) and step (f), the source 36 and the drain 37 are formed on the substrate 31 and laterally contact the first semiconductor layer 321, the second semiconductor layer 322 and the semiconductor passivation layer 3. In step (f), in addition to being formed on the semiconductor passivation layer 33, the gate dielectric layer 35 is also formed on the source 36 and the drain 37.

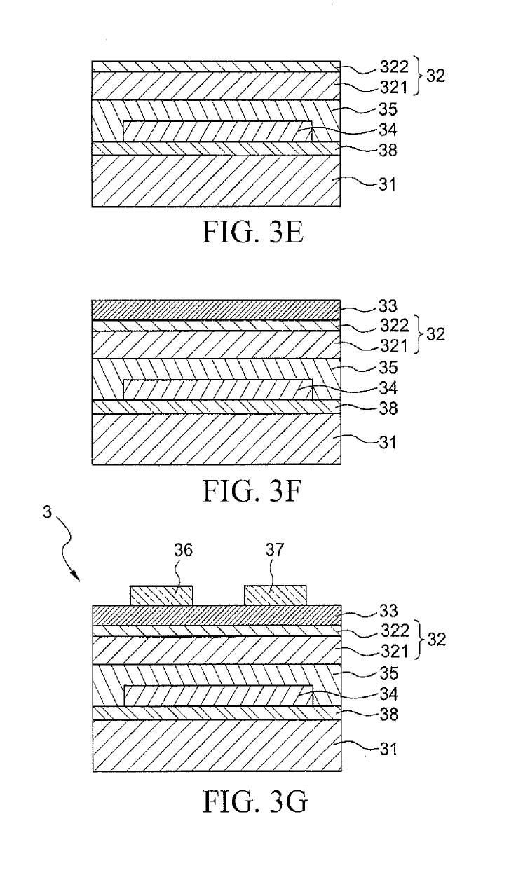

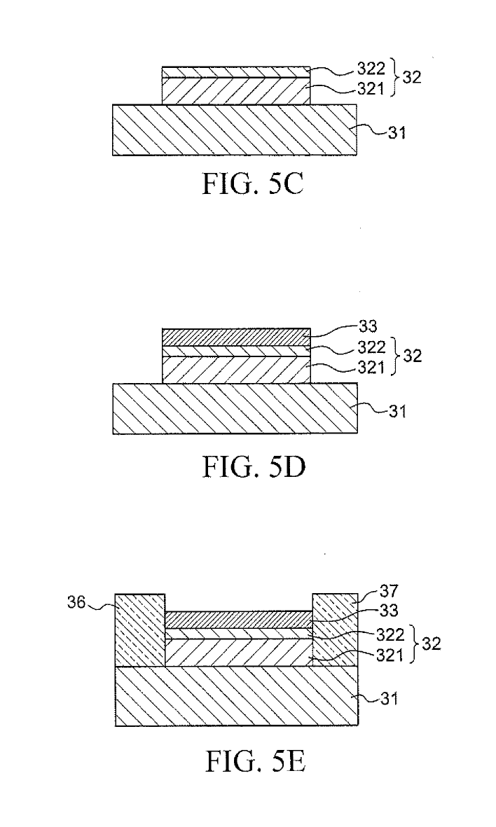

In the step of forming a double channel semiconductor layer 32 in the present embodiments, to make the double channel semiconductor layer 32 of the TFT 3, 3′ according to the present embodiments more semiconducting and have fewer defects, the following steps are further included: (1) forming a first layer 301 made of the metallic oxide semiconductor material, as shown in FIG. 3C or 5A; (2) forming a second layer 302 made of the oxygen gettering metal on the first layer 301 of the metallic oxide semiconductor material; (3) forming a barrier layer 303 on the second layer 302 of the oxygen gettering metal, as shown in FIG. 3D or 5B; (4) annealing to disperse and dope the oxygen gettering metal of the second layer 302 into the first layer 301 of the metallic oxide semiconductor material, such that the second layer 302 of the oxygen gettering metal and the first layer 301 of the metallic oxide semiconductor material form the second semiconductor layer 322, and in the first layer 301 formed by the metallic oxide semiconductor material, the rest of the first layer 301 is affected little or not affected by dispersion, and doping forms the first semiconductor layer 321; and (5) removing the barrier layer 303, as shown in FIG. 3E or 5C.

The manufacturing conditions and materials regarding the step of forming a double channel semiconductor layer 32 are described in detail as follows. In step (4), an annealing temperature of the annealing is 100-900° C. Preferably, the annealing temperature of the annealing is 100-600° C. The barrier layer 303 may be made of SiO₂. In step (4), the annealing atmosphere of the annealing is nitrogen, oxygen or argon. Preferably, the annealing atmosphere of the annealing in step (4) is argon.

The substrate 31 may be a semiconductor substrate, for example, a silicon substrate; may also be an insulating substrate such as a plastic substrate or a glass substrate; or may be a metal substrate. The metallic oxide semiconductor material may be IGZO, IGO, IZO, GZO, ZnO or other similar materials. Preferably, the metallic oxide semiconductor material is IGZO. The oxygen gettering metal doped in the second semiconductor layer 322 may be W, Sb, Ti, Sn, Al, Hf, Ga, La, Y, Sc or other similar materials. Preferably, the oxygen gettering metal is Ti, A thickness of the second semiconductor layer 322 is 1-100 nm. Preferably, the thickness of the second semiconductor layer 322 is 1-20 nm. The semiconductor passivation layer 33 may be made of TiO₂, PbZrTiO₃, BaTiO, SrTiO, ZnO, SnO₂, NiO, Ga₂O₃, Nb₂O₅, CeO₂, Cr₂O₃, Mn₂O₃, WO₃, CoO, Co₃O₄, Fe₂O₃, In₂O₃, ITO, AZO (AlZnO) or other similar materials. A thickness of the semiconductor passivation layer 33 is 1-100 nm. Preferably, the thickness of the semiconductor passivation layer 33 is 1-20 nm. The gate 34 may be made of TaN, Al, titanium silver alloy (Ti/Ag), ITO, Mo or other similar materials. The gate dielectric layer 35 may be made of SiO₂, SiNₓ, HfO₂, Y₂O₃, TiO₂, GeO₂, Al₂O₃ or other similar materials.

Please refer to FIG. 3A to FIG. 3G, which illustrate a specific manufacturing process of the bottom-gate TFT 3 according to the first embodiment. As shown in FIG. 3A, an insulation layer 38 is formed on the substrate 31, As shown in FIG. 3B, a gate 34 is formed on the insulation layer 38 on the substrate 31, and a gate dielectric layer 35 is formed on the gate 34. As shown in FIG. 3C, a first layer 301 formed by the metallic oxide semiconductor material is formed on the gate dielectric layer 35. As shown in FIG. 3D, a second layer 302 formed by the oxygen gettering metal is formed on the first layer 301 of the metallic oxide semiconductor material, and a barrier layer 303 is formed on the second layer 302 of the oxygen gettering metal. Afterwards, annealing is carried out to disperse and dope the oxygen gettering metal of the second layer 302 into the first layer 301 of the metallic oxide semiconductor material, such that the second layer 302 of the oxygen gettering metal and the first layer 301 of the metallic oxide semiconductor material affected by dispersion and doping form the second semiconductor layer 322, and the rest of the first layer 301 of the metallic oxide semiconductor material forms the first semiconductor layer 321, and then the barrier layer 303 is removed. As shown in FIG. 3E, the first semiconductor layer 321 is formed on the gate dielectric layer 35, and the second semiconductor layer 322 is formed on the first semiconductor layer 321. Next, as shown in FIG. 3F, a semiconductor passivation layer 33 is formed on the second semiconductor layer 322. As shown in FIG. 3G, a source 36 and a drain 37 are formed on the semiconductor passivation layer 33.

FIG. 5A to FIG. 5G illustrate a specific manufacturing process of the top-gate TFT 3′ according to the second embodiment. As shown in FIG. 5A, a first layer 301 made of the metallic oxide semiconductor material is formed on the substrate 31. As shown in FIG. 5B, a second layer 302 made of the oxygen gettering metal is formed on the first layer 301 of the metallic oxide semiconductor material, and then a barrier layer 303 is formed on the second layer 302 of the oxygen gettering metal. Next, annealing is carried out to disperse and dope the oxygen gettering metal of the second layer 302 into the first layer 301 of the metallic oxide semiconductor material, such that the second layer 302 of the oxygen gettering metal and the first layer 301 of the metallic oxide semiconductor material affected by dispersion and doping form the second semiconductor layer 322, and the rest of the first layer 301 of the metallic oxide semiconductor material not affected by dispersion and doping forms the first semiconductor layer 321, and then the barrier layer 303 is removed. Afterwards, as shown in FIG. 5C, in a case after the barrier layer 303 is removed, the first semiconductor layer 321 is formed on the substrate 31, and the second semiconductor layer 322 is formed on the first semiconductor layer 321, Next, as shown in FIG. 5D, a semiconductor passivation layer 33 is formed on the second semiconductor layer 322. Then, as shown in FIG. 5E, a source 36 and a drain 37 are formed on the substrate 31 and contact the sides of first semiconductor layer 321, the second semiconductor layer 322 and the semiconductor passivation layer 33 with their sides. As shown in FIG. 5F, a gate dielectric layer 35 is formed on the semiconductor passivation layer 33, the source 36 and the drain 37. Finally, as shown in FIG. 5G, a gate 34 is formed on the gate dielectric layer 35.

To sum up, the present embodiments relate to manufacturing methods for forming a TFT 3, 3′, the method at least including (the order of the process is not distinguished in the following) (a) providing a substrate 31; (b) forming a double channel semiconductor layer 32, the double channel semiconductor layer 32 including: a first semiconductor layer 321 made of a metallic oxide semiconductor material and formed above the substrate 31; and a second semiconductor layer 322 made of the metallic oxide semiconductor material doped by an oxygen gettering metal and formed on the first semiconductor layer 321; (c) forming a semiconductor passivation layer 33 on the second semiconductor layer 322, wherein the semiconductor passivation layer 33 protects the double channel semiconductor layer 32 and is semiconducting; (d) forming a gate 34 above the substrate 31; (e) forming a gate dielectric layer 35 between the gate 34 and the double channel semiconductor layer 32; (t) forming a source 36 close to the double channel semiconductor layer 32, above the substrate 31 and electrically connected to the double channel semiconductor layer 32; and (g) forming a drain 37 spaced apart from the source 36, close to the double channel semiconductor layer 32, formed above the substrate 31 and electrically connected to the double channel semiconductor layer 32.

The TFT according to the present embodiments can mitigate the disadvantages in the prior art. The foregoing embodiments are preferred examples but certainly do not limit the scope of the claims.

What is claimed is:

1. A thin film transistor, comprising:
a substrate;
a double channel semiconductor layer comprising:
a first semiconductor layer made of a metallic oxide semiconductor material and formed above the substrate; and
a second semiconductor layer made of the metallic oxide semiconductor material doped by an oxygen gettering metal and formed on the first semiconductor layer;
a semiconductor passivation layer formed on the second semiconductor layer, wherein the semiconductor passivation layer protects the double channel semiconductor layer and is semiconducting;
a gate formed above the substrate;
a gate dielectric layer formed between the gate and the double channel semiconductor layer;
a source close to the double channel semiconductor layer, formed above the substrate and electrically connected to the double channel semiconductor layer; and
a drain spaced apart from the source, close to the double channel semiconductor layer, formed above the substrate and electrically connected to the double channel semiconductor layer.

2. The thin film transistor according to claim 1, wherein the gate is formed on the substrate, the gate dielectric layer is formed on the gate, the first semiconductor layer is formed on the gate dielectric layer, and the source and the drain are formed on the semiconductor passivation layer.

3. The thin film transistor according to claim 2, wherein the thin film transistor further comprises:
an insulation layer formed between the substrate and the gate.

4. The thin film transistor according to claim 1, wherein the first semiconductor layer is formed on the substrate, the source and the drain are formed on the substrate and laterally contact the first semiconductor layer, the second semiconductor layer and the semiconductor passivation layer, the gate dielectric layer is formed on the semiconductor passivation layer, the source and the drain, and the gate is formed on the gate dielectric layer.

5. The thin film transistor according to claim 1, wherein the metallic oxide semiconductor material is IGZO, IGO, IZO, GZO, or ZnO.

6. The thin film transistor according to claim 5, wherein the metallic oxide semiconductor material is IGZO.

7. The thin film transistor according to claim 1, wherein the oxygen gettering metal is W, Sb, Ti, Sn, Al, Hf, Ga, La, Y, or Sc.

8. The thin film transistor according to claim 7, wherein the oxygen gettering metal is Ti.

9. The thin film transistor according to claim 1, wherein a thickness of the second semiconductor layer is 1-100 nm.

10. The thin film transistor according to claim 9, wherein the thickness of the second semiconductor layer is 1-20 nm.

11. The thin film transistor according to claim 1, wherein the semiconductor passivation layer is made of TiO₂, PbZrTiO₃, BaTiO, SrTiO, ZnO, SnO₂, NiO, Ga₂O₃, Nb₂O₅, CeO₂, Cr₂O₃, Mn₂O₃, WO₃, CoO, Co₃O₄, Fe₂O₃, In₂O₃, ITO or AZO (AlZnO).

12. The thin film transistor according to claim 1, wherein a thickness of the semiconductor passivation layer is 1-100 nm.

13. The thin film transistor according to claim 12, wherein the thickness of the semiconductor passivation layer is 1-20 nm.

14. A manufacturing method for forming a thin film transistor, comprising:
(a) providing a substrate;
(b) forming a double channel semiconductor layer, the double channel semiconductor layer comprising:
a first semiconductor layer made of a metallic oxide semiconductor material and formed above the substrate; and
a second semiconductor layer made of the metallic oxide semiconductor material doped by an oxygen gettering metal and formed on the first semiconductor layer;
(c) forming a semiconductor passivation layer on the second semiconductor layer, wherein the semiconductor passivation layer protects the double channel semiconductor layer and is semiconducting;
(d) forming a gate above the substrate;
(e) forming a gate dielectric layer between the gate and the double channel semiconductor layer;
(f) forming a source close to the double channel semiconductor layer, above the substrate and electrically connected to the double channel semiconductor layer; and
(g) forming a drain spaced apart from the source, close to the double channel semiconductor layer, above the substrate and electrically connected to the double channel semiconductor layer.

15. The manufacturing method according to claim 14, wherein step (b) comprises the following steps:
(b-1) forming a first layer of the metallic oxide semiconductor material;
(b-2) forming a second layer of the oxygen gettering metal on the first layer of the metallic oxide semiconductor material;
(b-3) forming a barrier layer on the second layer of the oxygen gettering metal;
(b-4) annealing to make the second layer of the oxygen gettering metal and the first layer of the metallic oxide semiconductor material form the second semiconductor layer and the rest of the first layer of the metallic oxide semiconductor material form the first semiconductor layer; and
(b-5) removing the barrier layer.

16. The manufacturing method according to claim 15, wherein the gate is formed on the substrate in step (d), the gate dielectric layer is formed on the gate in step (e), the first semiconductor layer is formed on the gate dielectric layer in step (b), and the source and the drain are formed on the semiconductor passivation layer in steps (f) and (g).

17. The manufacturing method according to claim 16, wherein the manufacturing method further comprises:
(h) forming an insulation layer between the substrate and the gate.

18. The manufacturing method according to claim 15, wherein the first semiconductor layer is formed on the substrate in step (b), the source and the drain are formed on the substrate and laterally contact the first semiconductor layer, the second semiconductor layer and the semiconductor passivation layer in steps (f) and (g), the gate dielectric layer is formed on the semiconductor passivation layer, the source and the drain in step (e), and the gate is formed on the gate dielectric layer in step (d).

19. The manufacturing method according to claim 15, wherein the metallic oxide semiconductor material is IGZO, IGO, IZO, GZO, or ZnO.

20. The manufacturing method according to claim 19, wherein the metallic oxide semiconductor material is IGZO.

21. The manufacturing method according to claim 15, wherein the oxygen gettering metal is W, Sb, Ti, Sn, Al, Hf, Ga, La, Y, or Sc.

22. The manufacturing method according to claim 21, wherein the oxygen gettering metal is Ti.

23. The manufacturing method according to claim 15, wherein a thickness of the second semiconductor layer is 1-100 nm.

24. The manufacturing method according to claim 23, wherein the thickness of the second semiconductor layer is 1-20 nm.

25. The manufacturing method according to claim 15, wherein the semiconductor passivation layer is made of TiO₂, PbZrTiO₃, BaTiO, SrTiO, ZnO, SnO₂, NiO, Ga₂O₃, Nb₂O₅, CeO₂, Cr₂O₃, Mn₂O₃, WO₃, CoO, Co₃O₄, Fe₂O₃, In₂O₃, ITO or AZO (AlZnO).

26. The manufacturing method according to claim 15, wherein a thickness of the semiconductor passivation layer is 1-100 nm.

27. The manufacturing method according to claim 26, wherein the thickness of the semiconductor passivation layer is 1-20 nm.

28. The manufacturing method according to claim 15, wherein annealing temperature of the annealing in step (b-4) is 100-900° C.

29. The manufacturing method according to claim 28, wherein the annealing temperature of the annealing in step (b-4) is 100-600° C.

30. The manufacturing method according to claim 15, wherein the barrier layer is made of SiO₂.

31. The manufacturing method according to claim 15, wherein annealing atmosphere of the annealing in step (b-4) is nitrogen, oxygen or argon.

32. The manufacturing method according to claim 31, wherein the annealing atmosphere of the annealing in step (b-4) is argon.
